(19) United States
(12) Patent Application Publication
(10) Pub. No.: US 2023/0165120 A1
(43) Pub. Date: May 25, 2023

(54) DISPLAY SUBSTRATE AND DISPLAY APPARATUS

(71) Applicants: Beijing BOE Sensor Technology Co., Ltd., Beijing (CN); BOE Technology Group Co., Ltd., Beijing (CN)

(72) Inventor: Zhonghuan LI, Beijing (CN)

(21) Appl. No.: 17/638,611

(22) PCT Filed: Feb. 22, 2021
(86) PCT No.: PCT/CN2021/077249

§ 371 Date: Feb. 25, 2022

(51) Int. Cl. H10K 59/80; H10K 59/65

(52) U.S. Cl. CPC H10K 59/8792; H10K 59/65; H10K 59/12

(57) ABSTRACT

Disclosed are a display substrate and a display apparatus including the same. The display substrate includes: a base substrate; a plurality of light-emitting devices, arranged on the base substrate; a plurality of photosensitive devices, arranged between a layer where the plurality of light-emitting devices are located and the base substrate, an orthographic projection, on the base substrate, of each photosensitive device is at a gap of adjacent orthographic projections, on the base substrate, of the light-emitting devices; a plurality of color filters and a black matrix, arranged on a side, facing away from the base substrate, of the layer where the plurality of light-emitting devices are located, the black matrix has a plurality of first openings and a plurality of second openings, the plurality of color filters are correspondingly arranged in the plurality of first openings and cover the plurality of light-emitting devices.

### CROSS-REFERENCE TO RELATED APPLICATION

This application is a national phase entry under 35 U.S.C § 371 of International Application No. PCT/CN2021/077249, filed Feb. 22, 2021.

### FIELD

The present disclosure relates to the field of display, in particular to a display substrate and a display apparatus.

### BACKGROUND

With constant development of a terminal technology, an electronic device is applied wider and wider. In order to protect information security of a user, a fingerprint recognition function is used on the electronic device more and more popular, for example, used for mobile phone unlocking, mobile payment (such as payment and transfer of account), etc.

### SUMMARY

Embodiments of the present disclosure provide a display substrate and a display apparatus. The solutions are as follows.

On the one hand, the embodiments of the present disclosure provide a display substrate, including:

a base substrate;

a plurality of light-emitting devices, arranged on the base substrate;

a plurality of photosensitive devices, arranged between a layer where the plurality of light-emitting devices are located and the base substrate, wherein orthographic projections, on the base substrate, of the plurality of photosensitive devices are at gaps of adjacent orthographic projections, on the base substrate, of the plurality of light-emitting devices; and

a plurality of color filters and a black matrix, arranged on a side, facing away from the base substrate, of the layer where the plurality of light-emitting devices are located, wherein the black matrix has a plurality of first openings and a plurality of second openings, the plurality of color filters are correspondingly arranged in the plurality of first openings and cover the plurality of light-emitting devices, and orthographic projections, on the base substrate, of the plurality of second openings are overlapped with the orthographic projections, on the base substrate, of the plurality of photosensitive devices.

Optionally, in the above display substrate provided by the embodiments of the present disclosure, at least one second opening is arranged corresponding to a respective one of the photosensitive devices.

Optionally, in the above display substrate provided by the embodiments of the present disclosure, an orthographic projection, on the base substrate, of the second opening is covered by an orthographic projection, on the base substrate, of the respective one photosensitive device.

Optionally, in the above display substrate provided by the embodiments of the present disclosure, a shape of the second opening is roughly a circle or a regular polygon.

Optionally, in the above display substrate provided by the embodiments of the present disclosure, a pore diameter, when the second opening is the circle, of the second opening is 2 μm-20 μm; or a length of a diagonal line, when the second opening is the regular polygon, of the second opening is 2μm-20 μm.

Optionally, in the above display substrate provided by the embodiments of the present disclosure, in a direction perpendicular to the base substrate, a thickness of the black matrix is 1 μm-5 μm.

Optionally, the above display substrate provided by the embodiments of the present disclosure further includes: a plurality of convex lenses arranged on a side, away from the base substrate, of the black matrix; and

the convex lenses and the second openings are arranged in a one-to-one correspondence mode, convex faces of the convex lenses face away from the photosensitive devices, and the convex lenses are configured to converge light rays, within a preset angle range, reflected by fingers to the photosensitive devices via the second openings.

Optionally, in the above display substrate provided by the embodiments of the present disclosure, orthographic projections, on the base substrate, of the convex lenses completely cover the orthographic projections, on the base substrate, of the second openings.

Optionally, in the above display substrate provided by the embodiments of the present disclosure, centers of the orthographic projections, on the base substrate, of the convex lenses are coincided with centers of the orthographic projections, on the base substrate, of the second openings.

Optionally, in the above display substrate provided by the embodiments of the present disclosure, each of the convex lenses is configured to converge light rays with different angles within the preset angle range to at least two intersection points, an orthographic projection, on the base substrate, of one of the intersection points is coincided with a centers of an orthographic projection, on the base substrate, of the each convex lenses, and orthographic projections, on the base substrate, of the rest of intersection points shift a distance relative to the centers of the orthographic projections, on the base substrate, of the each convex lenses.

Optionally, in the above display substrate provided by the embodiments of the present disclosure, a refractive index of the convex lenses is 1.6-1.8, and a curvature radius of the convex lenses is 5 μm-20 μm.

Optionally, the above display substrate provided by the embodiments of the present disclosure further includes: a transparent bonding layer arranged on a side, facing away from the base substrate, of a layer where the plurality of convex lenses are located, and a refractive index of the transparent bonding layer is smaller than the refractive index of the convex lenses.

Optionally, in the above display substrate provided by the embodiments of the present disclosure, the refractive index of the transparent bonding layer is 1.35-1.45.

Optionally, the above display substrate provided by the embodiments of the present disclosure further includes: a plurality of light-filtering structures, one light-filtering structure is arranged in each second opening, and the plurality of light-filtering structures are configured to filter infrared light rays.

Optionally, in the above display substrate provided by the embodiments of the present disclosure, a material of the light-filtering structures is green resin.

Optionally, in the above display substrate provided by the embodiments of the present disclosure, a surface, away from the base substrate, of the light-filtering structures is flush with a surface, away from the base substrate, of the black matrix.

Optionally, in the above display substrate provided by the embodiments of the present disclosure, a distance from a surface, away from the base substrate, of the light-filtering structures to the base substrate is smaller than or greater than a distance from a surface, away from the base substrate, of the black matrix to the base substrate.

Optionally, the above display substrate provided by the embodiments of the present disclosure further includes: a light-shading layer arranged on a side, facing the base substrate, of the black matrix, and the light-shading layer has a plurality of third openings; and

the plurality of third openings and the plurality of second openings are in one-to-one correspondence, and orthographic projections, on the base substrate, of the third openings and the orthographic projections, on the base substrate, of the second openings are at least partially coincided.

Optionally, in the above display substrate provided by the embodiments of the present disclosure, the orthographic projections, on the base substrate, of the third openings are in orthographic projections, on the base substrate, of the second openings corresponding to the third openings, and centers of the orthographic projections, on the base substrate, of the third openings are coincided with centers of the orthographic projections, on the base substrate, of the corresponding second openings corresponding to the third openings.

Optionally, in the above display substrate provided by the embodiments of the present disclosure, a shape of the third openings is roughly a circle or a regular polygon.

Optionally, in the above display substrate provided by the embodiments of the present disclosure, pore diameters, when the third openings are the circle, of the third openings are 2 μm-10 μm; or lengths of diagonal lines, when the third openings are the regular polygon, of the third openings are 2 μm-10 μm.

Optionally, in the above display substrate provided by the embodiments of the present disclosure, in the direction perpendicular to the base substrate, a thickness of the light-shading layer is 3000 Å-2 μm.

Optionally, in the above display substrate provided by the embodiments of the present disclosure, a material of the light-shading layer is metal, and the thickness of the light-shading layer is 3000 Å-5000 Å.

Optionally, in the above display substrate provided by the embodiments of the present disclosure, a material of the light-shading layer is same as a material of the black matrix, and the thickness of the light-shading layer is 0.5 μm-2 μm.

Optionally, the above display substrate provided by the embodiments of the present disclosure further includes: an encapsulation layer arranged between the layer where the plurality of light-emitting devices are located and a layer where the plurality of color filters are located; and

the light-shading layer is between a layer where first electrodes of the light-emitting devices are located and the encapsulation layer.

Optionally, in the above display substrate provided by the embodiments of the present disclosure, the light-shading layer and second electrodes of the light-emitting devices are arranged on the same layer.

On the other hand, the embodiments of the present disclosure further provide a display apparatus, including the above display substrate.

### BRIEF DESCRIPTION OF THE DRAWINGS

FIG. 1 is a schematic structural diagram of a display substrate provided by an embodiment of the present disclosure.

FIG. 2 is a schematic diagram of a sectional structure along a line I-II in FIG. 1.

FIG. 3 is a schematic structural diagram of a Z₁ region in FIG. 2.

FIG. 4 is a schematic diagram of light ray converging provided by an embodiment of the present disclosure.

FIG. 5 is a schematic diagram of another sectional structure along a line I-II in FIG. 1.

FIG. 6 is a schematic structural diagram of a Z₂ region in FIG. 5.

FIG. 7 is a schematic diagram of another sectional structure along a line I-II in FIG. 1.

FIG. 8 is a schematic structural diagram of a Z₃ region in FIG. 7.

### DETAILED DESCRIPTION OF THE EMBODIMENTS

In order to make the objective, solutions and advantages of the embodiments of the present disclosure more clear, the solutions of the embodiments of the present disclosure will be described clearly and completely with reference to the drawings of the embodiments of the present disclosure. It should be noted that the sizes and shapes of all graphs in the drawings do not reflect the true scale, and only intend to illustrate the content of the present disclosure. The same or similar reference numbers represent the same or similar elements or elements with the same or similar functions from beginning to end. Obviously, the described embodiments are part of the embodiments of the present disclosure, but not all the embodiments. On the basis of the described embodiments of the present disclosure, all other embodiments obtained by those ordinarily skilled in the art without inventive efforts fall within the protection scope of the present disclosure.

Unless otherwise defined, the technical or scientific terms used here shall have usual meanings understood by a person of ordinary skill in the art to which the present disclosure belongs. The words “first”, “second” and the like used in the specification and claim of the present disclosure do not indicate any order, quantity or importance, but are only used to distinguish different components. The word “including” or “comprising” and the like, means that an element or item preceding the word comprises an element or item listed after the word and the equivalent thereof, without excluding other elements or items. The words “inner”, “outer”, “upper”, “lower” and the like are only configured to indicate the relative positional relationship. When the absolute position of a described object changes, the relative positional relationship may also change accordingly.

In an Organic Light-Emitting Diode (OLED) display screen, a solution of Color Filter On Encapsulation (COE) may utilizes a color film to replace a polarizer, so that the OLED display screen has the characteristics of being higher in integration and thinner, and a large amount of production cost is saved.

An under-screen fingerprint recognition technology may integrate a fingerprint collecting module on a back face (namely, an opposite side of a display face) of the display screen without occupy a display region of the display screen, therefore, the under-screen fingerprint recognition technology has become an important implementation mode of fingerprint recognition. However, when the under-screen fingerprint recognition technology is applied to the OLED display screen based on a COE technology, because the color film includes a color filter and a black matrix (BM), existence of the black matrix causes significant reducing of light transmittance of the OLED display screen, and the under-screen fingerprint collecting module cannot sense a clear fingerprint signal.

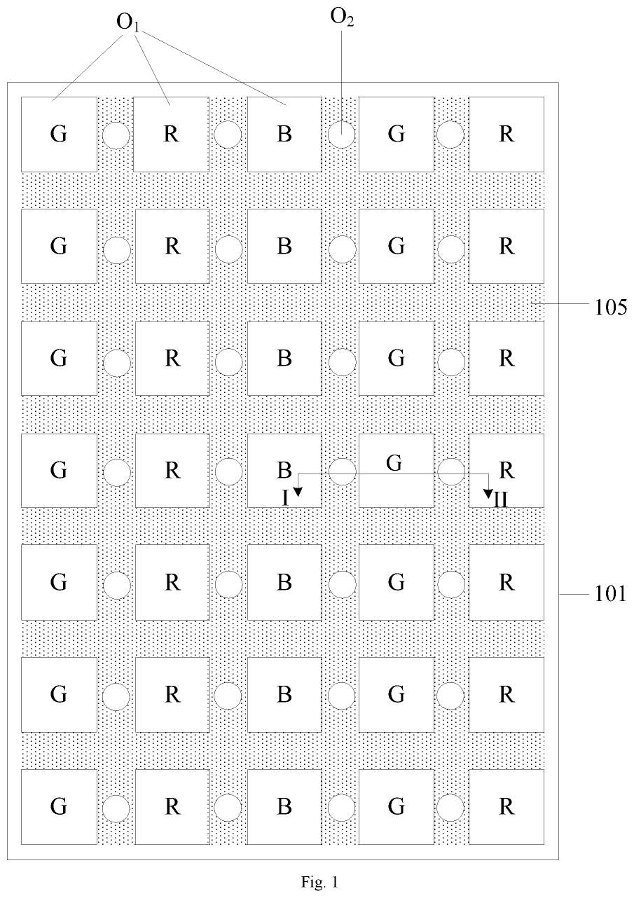

In order to at least solve the above technical problem existing in the related technology, the embodiments of the present disclosure provide a display substrate, as shown in FIG. 1 to FIG. 3, which may include:

a base substrate 101;

a plurality of light-emitting devices 102, arranged on the base substrate 101;

a plurality of photosensitive devices 103, arranged between a layer where the plurality of light-emitting devices 102 are located and the base substrate 101, wherein orthographic projections, on the base substrate 101, of the plurality of photosensitive devices 103 are at gaps of adjacent orthographic projections, on the base substrate 101, of the plurality of light-emitting devices 102; and

a plurality of color filters 104 and a black matrix 105, arranged on a side, facing away from the base substrate 101, of the layer where the plurality of light-emitting devices 102 are located, and the black matrix 105 has a plurality of first openings O₁ and a plurality of second openings O₂, the plurality of color filters 104 are correspondingly arranged in the plurality of first openings O₁ and cover the plurality of light-emitting devices 102, and orthographic projections, on the base substrate 101, of the plurality of second openings O₂ are overlapped with the orthographic projections, on the base substrate 101, of the plurality of photosensitive devices 103.

In the above display substrate provided by the embodiments of the present disclosure, by arranging the plurality of second openings O₂ mutually overlapped with the plurality of photosensitive devices 103 in the black matrix 105, transmittance of light rays reflected by fingerprints is effectively improved. Moreover, by integrating the photosensitive devices 103 in the display substrate, compared with a relevant solution that a photosensitive device 103 is located below the display substrate, a propagation path of the light rays reflected by the fingerprints is greatly shortened, and light energy loss is reduced. Therefore, by adopting the above technical solution provided by the present disclosure, clarity of fingerprint recognition can be effectively improved. In addition, because the photosensitive devices 103 are arranged at the gap of the adjacent light-emitting devices 102, the existence of the photosensitive device 103 does not affect light emitting of the light-emitting devices 102, so as to ensure a display effect.

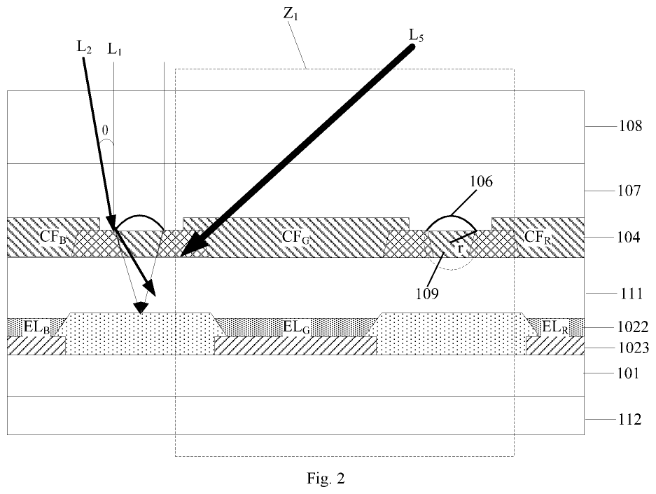

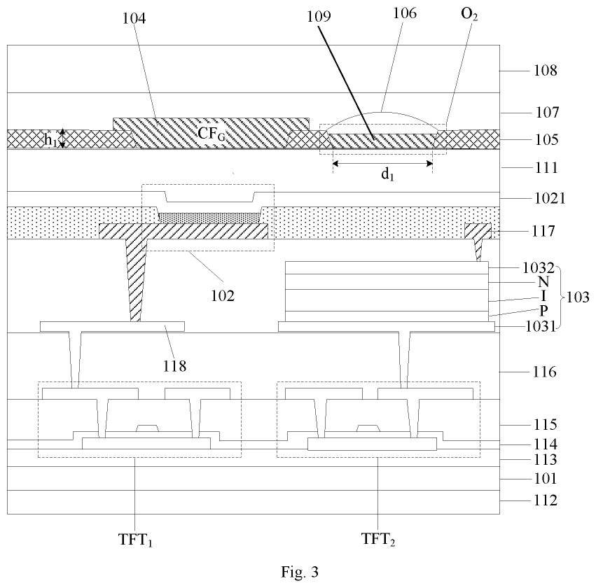

In some embodiments, as shown in FIG. 2 and FIG. 3, the light-emitting devices 102 may include first electrodes 1021, light-emitting functional layers 1022 and second electrodes 1023; the light-emitting functional layers 1022 include but are not limited to a hole injection layer, a hole transmission layer, an electron blocking layer, a light-emitting material layer, a hole blocking layer, an electron transmission layer and an electron injection layer. Specifically, the light-emitting functional layers 1022 may be a red light-emitting functional layer EL_{R}, a green light-emitting functional layer EL_{G} and a blue light-emitting functional layer EL_{B}. Accordingly, the color filters 104 may include a red color filter CF_{R}, a green color filter CF_{G} and a blue color filter CF_{B}. In addition, the photosensitive devices 103 may include bottom electrodes 1031, top electrodes 1032 and PIN structures arranged between the bottom electrodes 1031 and the top electrodes 1032. The PIN structures may include P-type semiconductor layers, intrinsic semiconductor layers I and N-type semiconductor layers. The P-type semiconductor layers are located between the bottom electrodes 1031 and the intrinsic semiconductor layers I, and the N-type semiconductor layers are located between the intrinsic semiconductor layers I and the top electrodes 1032; or the N-type semiconductor layers are located between the bottom electrodes 1031 and the intrinsic semiconductor layers I, and the p-type semiconductor layers are located between the intrinsic semiconductor layers I and the top electrodes 1032.

It should be noted that in the present disclosure, the color filters 104 are arranged over the light-emitting devices 102, the black matrix 105 is arranged over the gap between the adjacent light-emitting devices 102, FIG. 1 schematically gives an arrangement mode (equivalent to an arrangement mode of the light-emitting devices 102) of the color filters 104, during implementation, it may be other arrangement modes known by those skilled in the art, which is not limited here. In addition, FIG. 1 only shows that column gaps of the light-emitting devices 102 have the photosensitive devices 103 (a position corresponding to the second openings O₂). In some embodiments, the photosensitive devices 103 may further be arranged at the row gaps of the light-emitting devices 102.

optionally, in the above display substrate provided by the embodiments of the present disclosure, as shown in FIG. 3, the at least one second openings O₂ may be arranged to be corresponding to a respective one of the photosensitive devices 103, that is, one or more second openings O₂ may be arranged above one photosensitive device 103, so that the light transmittance of a position where each photosensitive device 103 is located is improved due to the second openings O₂, thereby improving a fingerprint recognition effect.

Optionally, in the above display substrate provided by the embodiments of the present disclosure, as shown in FIG. 3, an orthographic projection, on the base substrate 101, of the at least one second opening O₂ is in an orthographic projection, on the base substrate 101, of the respective one photosensitive device 103. The photosensitive devices 103 can convert received light rays into electric signals to achieve a fingerprint recognition function. By setting the orthographic projection, on the base substrate 101, of the second opening O₂ be located in the orthographic projections, on the base substrate 101, of the respective one photosensitive device 103, light rays transmitted through the second openings O2 may all be irradiated onto the photosensitive devices 103, so that intensity of the light rays received by the photosensitive devices 103 may be improved, thereby providing an obvious electric signal, and ensuring fingerprint clarity.

Optionally, in the above display substrate provided by the embodiments of the present disclosure, because large-angle light rays will interfere fingerprint recognition, in order to ensure that approximately collimated small-angle light rays (for example, light rays L₁-L₂ in a θ range as shown in FIG. 2) penetrate through the second openings O₂ to be irradiated to the photosensitive devices 103, as shown in FIG. 1 and FIG. 3, with reference to display screens with different resolutions, a shape of the second openings O₂ may be set roughly be a circle or a regular polygon (such as a regular hexagon and the like), and a pore diameter d₁, when the second opening O₂ is the circle, of the second opening is 2 μm-20; or a length of a diagonal line, when the second opening O₂ is the regular polygon, of the second opening is 2 μm-20 μm.

It should be noted that the greater the resolution of the display screen is, the smaller a line width of the black matrix 105 is, and accordingly, the smaller a size of the second openings O₂ is. In addition, in some embodiments, the shape of the second openings O₂ may also be a square or other shapes, as long as a function of transmitting the small-angle light rays can be achieved.

Optionally, in the above display substrate provided by the embodiments of the present disclosure, as shown in FIG. 3, in a direction perpendicular to the base substrate 101, a thickness h₁ of the black matrix 105 is 1 μm-5 μm. Under this thickness, the black matrix 105 can make the light transmittance of the light rays within a range of 400 nm-850 nm to be 0.1% or below, that is, can effectively intercept the light rays within the range of 400 nm-850 nm, so as to avoid crosstalk of emergent light rays of the adjacent color filters 104.

Optionally, the above display substrate provided by the embodiments of the present disclosure, as shown in FIG. 2 and FIG. 3, may further include: a plurality of convex lenses 106 arranged on a side, away from the base substrate 101, of the black matrix 105. The convex lenses 106 and the second openings O₂ are arranged in a one-to-one correspondence mode, convex faces of the convex lenses 106 face away from the photosensitive devices 103, and the convex lenses 106 are configured to converge light rays L₁-L₂, within a preset angle θ (such as 10°) range, reflected by fingers to the photosensitive devices 103 via the second openings O₂, thereby further ensuring that the approximately-collimated small-angle light rays are irradiated to the photosensitive devices 103, and thus improving accuracy of fingerprint recognition.

Optionally, the above display substrate provided by the embodiments of the present disclosure, as shown in FIG. 2 and FIG. 3, orthographic projections, on the base substrate 101, of the convex lenses 106 completely cover the orthographic projections, on the base substrate 101, of the corresponding second openings O₂, so as to ensure that all the light rays L₁-L₂ within the preset angle θ (such as 10°) range can be converged by the convex lenses 106 and irradiated to the photosensitive devices 103 through the second openings O₂.

Optionally, in the above display substrate provided by the embodiments of the present disclosure, centers of the orthographic projections, on the base substrate 101, of the convex lenses 106 are coincided with centers of the orthographic projections, on the base substrate 101, of the corresponding second openings O₂. By setting the centers of the orthographic projections, on the base substrate 101, of the convex lenses 106 be coincided with the centers of the orthographic projections of the second openings O₂ completely covered with the convex lenses 106, the second openings O₂ with the small size may also completely transmit the converged light rays of the convex lenses 106 to the photosensitive devices 103, so as to effectively ensure a collimation effect of fingerprint reflected light on the basis of improving a fingerprint reflected light intensity received by the photosensitive devices 103.

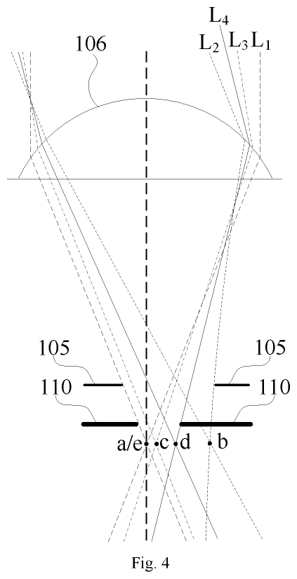

Optionally, in the above display substrate provided by the embodiments of the present disclosure, as shown in FIG. 4, each of the convex lenses 106 may converge light rays L₁ (such as an included angle with a vertical direction being 0°), L₃ (such as the included angle with the vertical direction being 3°), L₄ (such as the included angle with the vertical direction being 5°) and L₂ (such as the included angle with the vertical direction being 10°) with different angles within the preset angle θ (such as 10°) range to at least two intersection points (such as four intersection points a, b, c and d), an orthographic projection, on the base substrate 101, of one of the intersection points (such as the intersection point a) is coincided with a center e of an orthographic projection, on the base substrate 101, of the each convex lenses 106, and orthographic projections, on the base substrate 101, of the rest of intersection points (such as the three intersection points b, c and d) shift a distance relative to the center e of the orthographic projection, on the base substrate 101, of the each convex lenses 106. The distance is related to the angles of the light rays and a refractive index of the convex lenses 106, the larger the angle of the light rays is, the large a distance from the intersection point converged by the convex lenses 106 to the centers e of the orthographic projections of the convex lenses 106 is.

It can be seen from FIG. 4 that on the basis that the convex lenses 106 converge the light rays L₁ (such as the included angle with the vertical direction being 0°), L₃ (such as the included angle with the vertical direction being 3°), L₄ (such as the included angle with the vertical direction being 5°) and L₂ (such as the included angle with the vertical direction being 10°) with the different angles within the preset angle θ (such as 10°) range to the at least two intersection points (such as the four intersection points a, b, c and d), a light-shading layer 110 may be additionally arranged to selectively transmit the light rays with the different angles. For example, the light-shading layer 110 in FIG. 4 may selectively shade the intersection point (such as the intersection point d) of the large-angle light ray (such as L₂), and selectively transmit the small-angle light rays (such as L₁, L₃ and L₄), so as to further improve a collimation effect.

Optionally, in the above display substrate provided by embodiments of the present disclosure, the refractive index of the convex lenses 106 may be 1.6-1.8, and a curvature radius r of the convex lenses 106 may be 5 μm-20 μm, as shown in FIG. 2. The convex lenses 106 with the large refractive index have a good converging effect on the light rays, and the curvature radius within the above range can meet different product demands. Accordingly, the curvature radius r within the above range can ensure that an upper surface of the photosensitive devices 103 is in the neighborhood of a focal point of the convex lenses 106.

Optionally, the above display substrate provided by the embodiments of the present disclosure, as shown in FIG. 2 and FIG. 3, may further include: a transparent bonding layer 107 arranged on a side, facing away from the base substrate 101, of a layer where the plurality of convex lenses 106 are located, and a refractive index of the transparent bonding layer 107 is smaller than the refractive index of the convex lenses 106, so as to match the refractive index of the convex lenses 106. Meanwhile, the transparent bonding layers 107 are further configured to bond and fix a protective cover plate 104 with the color filters 104, the black matrix 105 and the convex lenses 106.

Optionally, in the above display substrate provided by the embodiments of the present disclosure, in order to match the refractive index of the convex lenses 106 better, the refractive index of the transparent bonding layers 107 may be 1.35-1.45. In some embodiments, the transparent bonding layers 107 may be optically clear adhesive (OCA).

Optionally, the above display substrate provided by the embodiments of the present disclosure, as shown in FIG. 2 and FIG. 3, may further include: a plurality of light-filtering structures 109, one light-filtering structure 109 is arranged in each second opening O₂, and the plurality of light-filtering structures 109 are configured to filter infrared light rays.

Because in a fingerprint recognition process, light emitted by the light-emitting devices 102 may be sensed by the photosensitive devices 103 after being reflected by the fingerprints, in addition, the photosensitive devices 103 may further sense ambient light incident through the fingers. The ambient light may generate interference on the fingerprint recognition of the photosensitive devices 103. For example, when the ambient light is irradiated over the fingers, the ambient light penetrate through the fingers and stimulate biological tissues in the fingers to emit pigment light, and the pigment light may generate the interference on the fingerprint recognition. Through detection, the pigment light mainly includes light with a wavelength being 600 nm or above. Therefore, the light-filtering structures 109 arranged at the second openings O₂ may effectively avoid influence of the ambient light by intercept the infrared light rays, thereby achieving an effect of accurate fingerprint recognition under an outdoor sunlight environment.

Optionally, in the above display substrate provided by the embodiments of the present disclosure, a material of the light-filtering structures 109 may be green resin. The green resin is a material of green color filter CF_{G}, and can effectively intercept the light rays of 580 nm-850 nm. Certainly, during specific implementation, the light-filtering structures 109 may further be manufactured by selecting other materials other than the green resin, as long as a function of cutting-off the infrared light rays can be achieved.

It should be noted that when a cutting-off effect of the infrared light rays is achieved, the light-filtering structures with different materials needs different thicknesses, so that reserved spaces in the second openings O₂ are different. Therefore, in some embodiments, a surface, away from the base substrate 101, of the light-filtering structures 109 is flush with a surface, away from the base substrate 101, of the black matrix 105, that is, the light-filtering structures 109 exactly fill the second openings O₂. At this time, bottoms of the convex lenses 106 and an upper surface of the black matrix 105 are exactly arranged in a co-planar arrangement. In some other embodiments, a distance from the surface, away from the base substrate 101, of the light-filtering structures 109 to the base substrate 101 may be smaller than or greater than a distance from the surface, away from the base substrate 101, of the black matrix 105 to the base substrate 101. That is, the light-filtering structures 109 do not yet fill or overflows the second openings O₂. Accordingly, the bottoms of the convex lenses 106 are embedded into the second openings O₂ or are higher than the upper surface of the black matrix 105.

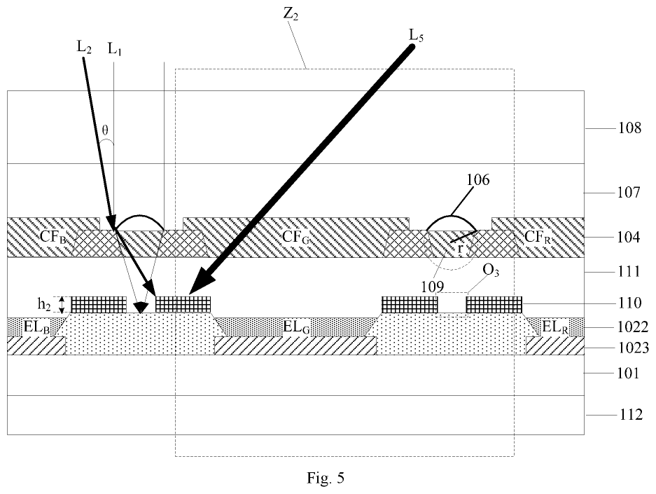

It can be known from the above description that the above display substrate provided by the embodiments of the present disclosure can utilize the approximately-collimated small-angle light rays for fingerprint recognition. However, in the fingerprint recognition process, some large-angle crosstalk light rays L₅ occur inevitably. In some embodiments, the crosstalk light rays L₅ can be blocked by the black matrix 105, as shown in FIG. 2. But in some embodiments, the crosstalk light rays L₅ are not effectively intercepted by the black matrix 105, as shown in FIG. 5.

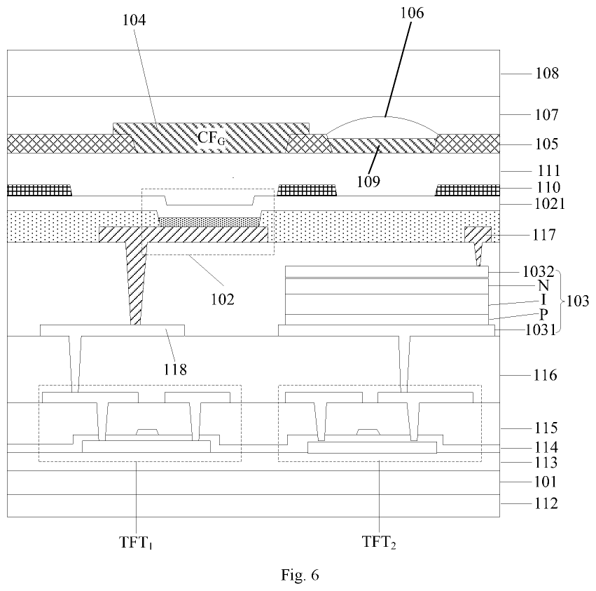

Based on this, in order to effectively intercept the crosstalk light rays L₅, in the above display substrate provided by the embodiments of the present disclosure, as shown in FIG. 5 and FIG. 6, a light-shading layer 110 may further be arranged on a side, facing the base substrate 110, of the black matrix 105. The light-shading layer 110 has a plurality of third openings O₃. The plurality of third openings O₃ and the plurality of second openings O₂ are in one-to-one correspondence, and orthographic projections, on the base substrate 101, of the third openings O₃ and the orthographic projections, on the base substrate 101, of the second openings O₂ are at least partially coincided. It can be seen from FIG. 5, the light-shading layer 110 can play a role in intercepting the crosstalk light rays L₅. The third openings O₃ and the second openings O₂ are correspondingly overlapped, a collimating effect can be achieved on the small-angle light rays L₁, L₃ and L₄, thereby improving the fingerprint recognition effect advantageously.

Optionally, in the above display substrate provided by the embodiments of the present disclosure, as shown in FIG. 5 and FIG. 6, in order to obtain the good collimating effect, the orthographic projections, on the base substrate 101, of the third openings O₃ may be arranged to be in the orthographic projections, on the base substrate 101, of the second openings O₂ corresponding to the third openings, and centers of the orthographic projections, on the base substrate 101, of the third openings O₃ are coincided with the centers of the orthographic projections, on the base substrate 101, of the second openings O₂ corresponding to the third openings.

Optionally, in the above display substrate provided by the embodiments of the present disclosure, in order to guarantee the collimation effect, a shape of the third openings O₃ may be roughly a circle or a regular polygon (such as a regular hexagon), and pore diameters, when the third openings O₃ are the circle, of the third openings are 2 μm-10 μm; or lengths of diagonal lines, when the third openings O₃ are the regular polygon, of the third opening are 2 μm-10 μm. In addition, in some embodiments, the shape of the third openings O₃ may also be a square or other shapes, as long as the function of collimating the small-angle light rays can be achieved.

Optionally, in the above display substrate provided by the embodiment of the present disclosure, as shown in FIG. 5, in the direction perpendicular to the base substrate 101, a thickness h₂ of the light-shading layer 110 is 3000 Å-2 μm. Under this thickness, the light-shading layer 110 can make the light transmittance of a crosstalk light ray L₃ within a range of 400 nm-850 nm less than 0.1%, that is, can effectively intercept the crosstalk light ray L₃ within the range of 400 nm-850 nm, so as to avoid influence of the crosstalk light ray L₃ on fingerprint recognition.

In some embodiments, the light-shading layer 110 may be manufactured by using light absorbing or low-reflectivity material such as the black matrix (BM) and molybdenum metal (Mu), so as to reduce a degree of reflecting of the large-angle crosstalk light ray L₃ on the light-shading layer 110, thereby improving the accuracy of the fingerprint recognition.

Optionally, in the above display substrate provided by the embodiments of the present disclosure, when a material of the light-shading layer is metal, the thickness of the light-shading layer 110 may be set to be 3000 Å-5000 Å in order to effectively intercept the crosstalk light ray L₃.

Optionally, in the above display substrate provided by the embodiments of the present disclosure, when the material of the light-shading layer 110 is same as a material of the black matrix 105 are the same, the thickness of the light-shading layer 110 may be set to be 0.5 μm-2 μm in order to effectively intercept the crosstalk light ray L₃.

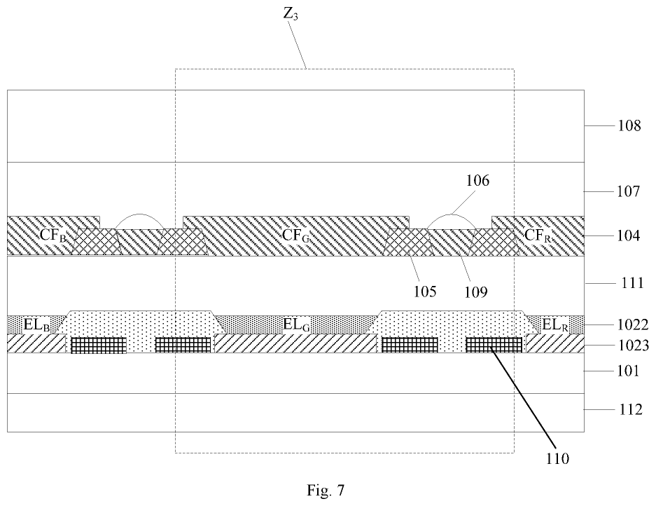

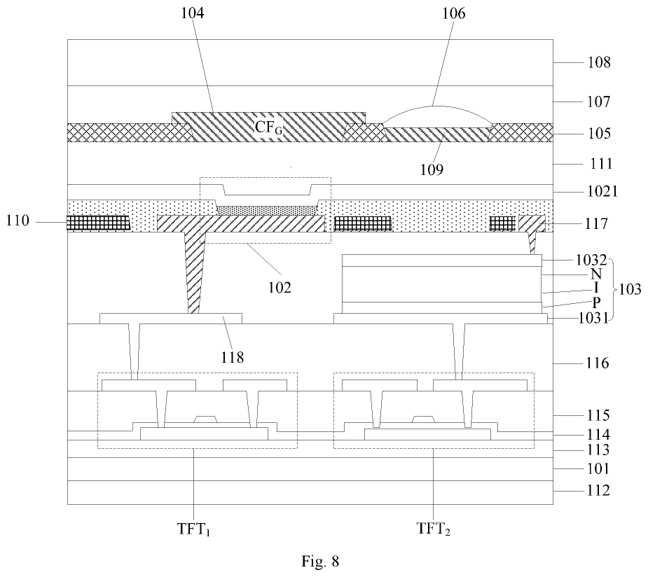

Optionally, the above display substrate provided by the embodiments of the present disclosure, as shown in FIG. 6, may further include: an encapsulation layer 111 located between the layer where the plurality of light-emitting devices 102 are located and a layer where the plurality of color filters 104 are located; and the light-shading layer 110 may be located between the first electrodes 1021 of the light-emitting devices 102 and the encapsulation layer 111. Or, as shown in FIG. 7 and FIG. 8, the light-shading layer 110 and the second electrodes 1023 of the light-emitting devices 102 may be arranged on the same layer. Optionally, the second electrodes 1023 may be anodes, and the first electrodes 1021 may be cathodes.

It should be noted that in the present disclosure, the “same layer” refers to a layer structure formed by utilizing the same mask through a single mask patterning process after a film layer for manufacturing specific graphics is formed by adopting the same film forming process. That is, the single mask patterning process corresponds to one mask (also called a photomask). According to the different specific graphics, the single mask patterning process may include a plurality of exposure, developing or etching processes, while the specific graphics in the formed layer structure may be continuous or discontinuous, and these specific graphics may be arranged at the same height or have the same thickness, or may be at the different heights or have the different thicknesses. It can be seen that in the case that the light-shading layer 110 and the second electrodes 1023 of the light-emitting devices 102 are arranged on the same layer, the light-shading layer 110 may be prevented from being separately arranged, thereby reducing the quantity of the film layers, facilitating achievement of thinning design, and saving a cost.

Generally, the above display substrate provided by the embodiment of the present disclosure, as shown in FIG. 2 to FIG. 8, may further include: a heat radiation film 112, a buffer layer 113, a gate insulating layer 114, an interlayer dielectric layer 115, a flattening layer 116, a bias line 117, a transfer electrode 118, a first transistor TFT₁ and a second transistor TFT₂, and the like. It should be understood by a person of ordinary skill in the art that the display substrate should have other essential constituent parts, which is not repeated here and should not be regarded as limitation to the present invention.

Based on the same inventive concept, the present disclosure further provides a display apparatus, including the above display substrate provided by the embodiments of the present disclosure. The display substrate may be an OLED display substrate. Principles of the display apparatus for solving the problems are similar to that of the above display substrate, therefore, implementation of the display apparatus may refer to the embodiments of the above display substrate, and repetitions are omitted.

In some embodiments, the above display apparatus provided by the embodiments of the present disclosure may be: any product or component with a display function, such as a mobile phone, a tablet computer, a television, a displayer, a notebook computer, a digital photo frame, a navigator, a smart watch, a fitness wristband and a personal digital assistant. The above display apparatus provided by the embodiments of the present disclosure may further include but not limited to: a radio frequency unit, a network module, an audio output unit, an input unit, a sensor, a display unit, a user input unit, an interface unit, a memory, a processor, a power supply and other components. Those skilled in the art may understand that composition of the above display apparatus does not form limitation to the display apparatus, and the display apparatus may include the above more or less components, or combine certain components, or different component arrangements.

Obviously, those skilled in the art can make various modifications and variations to the embodiments of the present invention without departing from the spirit and scope of the embodiments of the present invention. In this way, if these modifications and variations of the embodiments of the present invention and their equivalent art, the present invention also intends to include these modifications and variations.

1. A display substrate, comprising:
a base substrate;
a plurality of light-emitting devices, arranged on the base substrate;
a plurality of photosensitive devices, arranged between a layer where the plurality of light-emitting devices are located and the base substrate, wherein orthographic projections, on the base substrate, of the plurality of photosensitive devices are at gaps of adjacent orthographic projections, on the base substrate, of the plurality of light-emitting devices; and
a plurality of color filters and a black matrix, arranged on a side, facing away from the base substrate, of the layer where the plurality of light-emitting devices are located;
wherein the black matrix has a plurality of first openings and a plurality of second openings, the plurality of color filters are correspondingly arranged in the plurality of first openings and cover the plurality of light-emitting devices, and orthographic projections, on the base substrate, of the plurality of second openings are overlapped with the orthographic projections, on the base substrate, of the plurality of photosensitive devices.

2. The display substrate according to claim 1, wherein at least one second opening is arranged corresponding to a respective one of the photosensitive device.

3. The display substrate according to claim 2, wherein an orthographic projection, on the base substrate, of the second opening is covered by an orthographic projection, on the base substrate, of the respective one photosensitive device.

4. The display substrate according to claim 3, wherein a shape of the second opening is roughly a circle or a regular polygon.

5. The display substrate according to claim 4, wherein:
a pore diameter, when the second opening is the circle, of the second opening is 2 μm-20 μm; or
a length of a diagonal line, when the second opening is the regular polygon, of the second opening is 2 μm-20 μm.

6. The display substrate according to claim 1, wherein in a direction perpendicular to the base substrate, a thickness of the black matrix is 1 μm-5 82 m.

7. The display substrate according to claim 1, further comprising: a plurality of convex lenses arranged on a side, away from the base substrate, of the black matrix; wherein
the convex lenses and the second openings are arranged in a one-to-one correspondence mode, convex faces of the convex lenses face away from the photosensitive devices, and the convex lenses are configured to converge light rays, within a preset angle range, reflected by fingers to the photosensitive devices via the second openings.

8. The display substrate according to claim 7, wherein:
orthographic projections, on the base substrate, of the convex lenses completely cover the orthographic projections, on the base substrate, of the second openings; and
centers of the orthographic projections, on the base substrate, of the convex lenses are coincided with centers of the orthographic projections, on the base substrate, of the second openings.

9. (canceled)

10. The display substrate according to claim 8, wherein each of the convex lenses is configured to converge light rays with different angles within the preset angle range to at least two intersection points, an orthographic projection, on the base substrate, of one of the intersection points is coincided with a center of an orthographic projection, on the base substrate, of the each convex lenses, and orthographic projections, on the base substrate, of the rest of intersection points shift a distance relative to the center of the orthographic projection, on the base substrate, of the each convex lenses.

11. The display substrate according to claim 7, wherein a refractive index of the convex lenses is 1.6-1.8, and a curvature radius of the convex lenses is 5 μm-20 μm.

12. The display substrate according to claim 11, further comprising: a transparent bonding layer arranged on a side, facing away from the base substrate, of a layer where the plurality of convex lenses are located, and a refractive index of the transparent bonding layer is smaller than the refractive index of the convex lenses;
wherein the refractive index of the transparent bonding layer is 1.35-1.45.

13. (canceled)

14. The display substrate according to claim 1, further comprising: a plurality of light-filtering structures, wherein one light-filtering structure is arranged in each second opening, and the plurality of light-filtering structures are configured to filter infrared light rays.

15. The display substrate according to claim 14, wherein:
a material of the light-filtering structures is green resin;
a surface, away from the base substrate, of the light-filtering structures is flush with a surface, away from the base substrate, of the black matrix; and
a distance from a surface, away from the base substrate, of the light-filtering structures to the base substrate is smaller than or greater than a distance from a surface, away from the base substrate, of the black matrix to the base substrate.

16. (canceled)

17. (canceled)

18. The display substrate according to claim 1, further comprising: a light-shading layer arranged on a side, facing the base substrate, of the black matrix, wherein the light-shading layer has a plurality of third openings; and
the plurality of third openings and the plurality of second openings are in one-to-one correspondence, and orthographic projections, on the base substrate, of the third openings and the orthographic projections, on the base substrate, of the second openings are at least partially coincided.

19. The display substrate according to claim 18, wherein the orthographic projections, on the base substrate, of the third openings are in orthographic projections, on the base substrate, of the second openings corresponding to the third openings, and centers of the orthographic projections, on the base substrate, of the third openings are coincided with centers of the orthographic projections, on the base substrate, of the second openings corresponding to the third openings.

20. The display substrate according to claim 18, wherein
a shape of the third openings is roughly a circle or a regular polygon,
pore diameters, when the third openings are the circle, of the third openings are 2 μm-10 μm; or lengths of diagonal lines, when the third openings are the regular polygon, of the third openings are 2 μm-10 μm.

21. (canceled)

22. The display substrate according to claim 18, wherein in a direction perpendicular to the base substrate, a thickness of the light-shading layer is 3000 Å-2 μm.

23. The display substrate according to claim 22, wherein:
a material of the light-shading layer is metal, and the thickness of the light-shading layer is 3000 Å-5000 Å; or
a material of the light-shading layer is same as a material of the black matrix, and the thickness of the light-shading layer is 0.5 μm-2 μm.

24. (canceled)

25. The display substrate according to claim 18, further comprising: an encapsulation layer arranged between the layer where the plurality of light-emitting devices are located and a layer where the plurality of color filters are located; and
the light-shading layer is between a layer where first electrodes of the light-emitting devices are located and the encapsulation layer;
wherein the light-shading layer and second electrodes of the light-emitting devices are arranged on same layer.

26. (canceled)

27. A display apparatus, comprising the display substrate according to claim 1.
